(19) United States
(12) Patent Application Publication
(10) Pub. No.: US 2024/0096851 A1
(43) Pub. Date: Mar. 21, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Unbyoung Kang, Suwon-si (KR); Jeonggi Jin, Suwon-si (KR); Gilman Kang, Suwon-si (KR); Juil Choi, Suwon-si (KR); Dongchul Han, Suwon-si (KR)

(21) Appl. No.: 18/301,403

(22) Filed: Apr. 17, 2023

(30) Foreign Application Priority Data
Sep. 16, 2022 (KR) 10-2022-0117244

(51) Int. Cl. H01L 25/065; H01L 23/00; H01L 23/31; H01L 23/48; H01L 23/538

(52) U.S. Cl. CPC H01L 25/0657; H01L 23/3107; H01L 23/481; H01L 23/5389; H01L 24/19; H01L 2224/12105; H01L 2224/32146; H01L 2225/0651; H01L 2225/06548; H01L 2225/06555

(57) ABSTRACT

A semiconductor package includes a first redistribution structure, a first semiconductor chip on the first redistribution structure and including a first through-electrode, a second semiconductor chip on the first semiconductor chip and including a central portion vertically overlapping the first semiconductor chip and an outer portion horizontally offset from a sidewall of the first semiconductor chip, a molding layer in contact with the first redistribution structure, the first semiconductor chip, and the second semiconductor chip, a second redistribution structure on the second semiconductor chip and the molding layer, a first vertical connection wire extending through the molding layer and extending from the first redistribution structure to the second redistribution structure, and a second vertical connection wire extending through the molding layer and extending from the first redistribution structure to the outer portion of the second semiconductor chip.

### CROSS-REFERENCE TO RELATED APPLICATION

This application is based on and claims priority under 35 U.S.C. § 119 to Korean Patent Application No. 10-2022-0117244, filed on Sep. 16, 2022, in the Korean Intellectual Property Office, the disclosure of which is incorporated by reference herein in its entirety.

### BACKGROUND

The inventive concept relates to a semiconductor package and a method of manufacturing the semiconductor package.

Due to the rapid development of the electronics industry and user demand, electronic equipment is becoming increasingly smaller in size, more multi-functional, and larger in capacity. Therefore, semiconductor packages including a plurality of semiconductor chips are required. For example, methods of mounting various semiconductor chips on substrates side by side, methods of stacking semiconductor chips or packages on one package substrate, methods of mounting interposers, on which a plurality of semiconductor chips are mounted, on package substrates, and the like are being used.

### SUMMARY

The inventive concept provides a semiconductor package and a method of manufacturing the semiconductor package.

According to an aspect of the inventive concept, there is provided a semiconductor package including a first redistribution structure including a first redistribution pattern and a first redistribution insulating layer, a first semiconductor chip on the first redistribution structure and including a first semiconductor substrate and a first through-electrode extending through the first semiconductor substrate, a second semiconductor chip on the first semiconductor chip and including a central portion vertically overlapping the first semiconductor chip and an outer portion horizontally offset from a sidewall of the first semiconductor chip, an inter-chip connection bump between the first semiconductor chip and the second semiconductor chip, a molding layer in contact with the first redistribution structure, the first semiconductor chip, the second semiconductor chip, and the inter-chip connection bump, a second redistribution structure on the second semiconductor chip and the molding layer and including a second redistribution pattern and a second redistribution insulating layer, a first vertical connection wire extending through the molding layer and extending from the first redistribution structure to the second redistribution structure, and a second vertical connection wire extending through the molding layer and extending from the first redistribution structure to the outer portion of the second semiconductor chip.

According to another aspect of the inventive concept, there is provided a semiconductor package including a first redistribution structure including a first redistribution pattern and a first redistribution insulating layer, a first semiconductor chip on the first redistribution structure and including a first semiconductor substrate and a first through-electrode extending through the first semiconductor substrate, a first conductive connection pillar extending between a first lower connection pad of the first semiconductor chip and a first redistribution pad of the first redistribution structure, a second semiconductor chip on the first semiconductor chip and electrically connected to the first through-electrode, wherein an outer portion of the second semiconductor chip is laterally offset from a sidewall of the first semiconductor chip, an inter-chip connection bump between the first semiconductor chip and the second semiconductor chip, a second conductive connection pillar extending between a second lower connection pad of the second semiconductor chip and the inter-chip connection bump, a molding layer in contact with the first redistribution structure, the sidewall of the first semiconductor chip, a sidewall of the second semiconductor chip, and the inter-chip connection bump, a second redistribution structure on the second semiconductor chip and the molding layer and including a second redistribution pattern and a second redistribution insulating layer, a first vertical connection conductor extending through the molding layer and extending between the first redistribution structure and the second redistribution structure, and a second vertical connection conductor extending through the molding layer and extending between the first redistribution structure and the second semiconductor chip.

According to yet another aspect of the inventive concept, there is provided a semiconductor package including a first redistribution structure including a first redistribution pattern and a first redistribution insulating layer, a first semiconductor chip on the first redistribution structure and including a first semiconductor substrate and a first through-electrode extending through the first semiconductor substrate, a first conductive connection pillar between the first semiconductor chip and the first redistribution structure and including copper, a second semiconductor chip on the first semiconductor chip and including a central portion vertically overlapping the first semiconductor chip and an outer portion horizontally offset from a sidewall of the first semiconductor chip, an inter-chip connection bump between the first semiconductor chip and the second semiconductor chip and including solder, a second conductive connection pillar between the inter-chip connection bump and the second semiconductor chip and including copper, a molding layer in contact with the first redistribution structure, the first semiconductor chip, the second semiconductor chip, the first conductive connection pillar, the second conductive connection pillar, and the inter-chip connection bump, a second redistribution structure on the second semiconductor chip and the molding layer and including a second redistribution pattern and a second redistribution insulating layer, an upper semiconductor chip on the second redistribution structure, a first vertical connection wire extending through the molding layer between a first bonding pad of the first redistribution structure and a second bonding pad of the second redistribution structure, and a second vertical connection wire extending through the molding layer between a third bonding pad of the first redistribution structure and a fourth bonding pad of the second semiconductor chip, wherein a contact area between the first vertical connection wire and the second bonding pad is greater than a contact area between the first vertical connection wire and the first bonding pad, and a contact area between the second vertical connection wire and the fourth bonding pad is greater than a contact area between the second vertical connection wire and the third bonding pad.

According to yet another aspect of the inventive concept, there is provided a method of manufacturing a semiconductor package, the method including forming, on a carrier substrate, a second redistribution structure including a second redistribution pattern, mounting, on the second redistribution structure, a second semiconductor chip including a second semiconductor substrate and a second active layer on an active surface of the second semiconductor substrate, forming a first vertical connection wire, which extends in a vertical direction from a bonding pad of the second redistribution structure, and a second vertical connection wire, which extends in the vertical direction from a bonding pad of the second semiconductor chip, by performing a wire bonding process, mounting a first semiconductor chip on the second semiconductor chip using an inter-chip connection bump, wherein the first semiconductor chip includes a first semiconductor substrate, a first active layer on an active surface of the first semiconductor substrate, and a first through-electrode extending through the first semiconductor substrate, forming a molding layer on the first semiconductor chip, the second semiconductor chip, the first vertical connection wire, and the second vertical connection wire, polishing the molding layer to expose the first vertical connection wire and the second vertical connection wire, forming, on the first semiconductor chip and the molding layer, a first redistribution structure including a first redistribution pattern, which is electrically connected to the first vertical connection wire and the second vertical connection wire, and separating the carrier substrate from the second redistribution structure.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to some embodiments;

FIG. 2 is an enlarged view illustrating a region II of FIG. 1;

FIG. 3 is an enlarged view illustrating a region III of FIG. 1;

FIG. 4 is an enlarged view illustrating a region IV of FIG. 1;

FIG. 5 is an enlarged view illustrating a region V of FIG. 1;

FIG. 6 is a cross-sectional view illustrating a semiconductor package according to some embodiments;

FIG. 7 is a cross-sectional view illustrating a semiconductor package according to some embodiments;

FIG. 8 is an enlarged view illustrating a region VIII of FIG. 7;

FIG. 9 is an enlarged view illustrating a region IX of FIG. 7;

FIGS. 10A to 10H are cross-sectional views illustrating a method of manufacturing a semiconductor package, according to some embodiments; and

FIG. 11 is a plan view schematically illustrating a structure shown in FIG. 10B.

### DETAILED DESCRIPTION

Hereinafter, embodiments of the inventive concept will be described in detail with reference to the accompanying drawings. Like components are denoted by like reference numerals throughout the specification, and repeated descriptions thereof may be omitted in the interest of brevity.

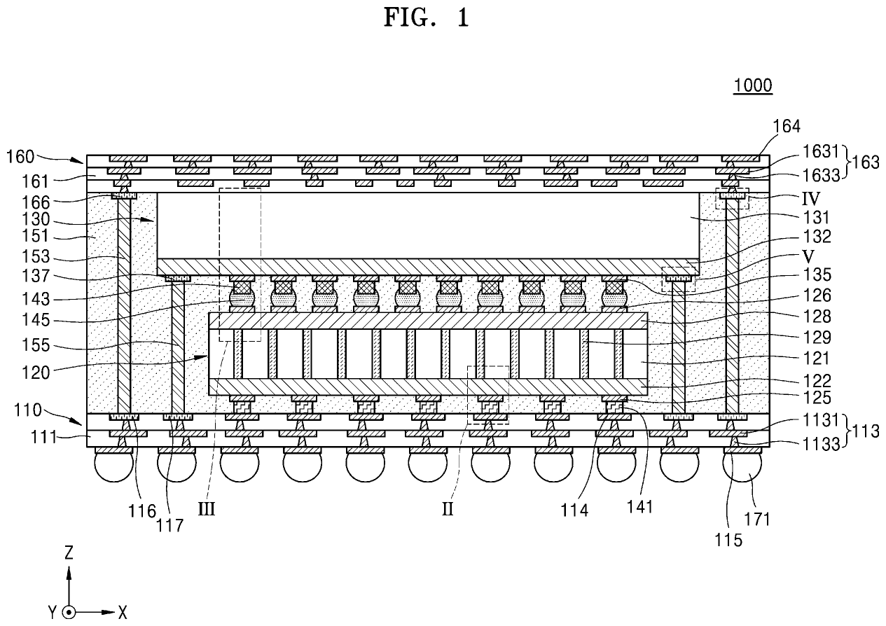

FIG. 1 is a cross-sectional view illustrating a semiconductor package 1000 according to some embodiments.

Referring to FIG. 1, the semiconductor package 1000 may include a first redistribution structure 110, a first semiconductor chip 120, a second semiconductor chip 130, a molding layer 151, a second redistribution structure 160, a first vertical connection conductor 153, and a second vertical connection conductor 155.

The first redistribution structure 110 may be a substrate on which the first semiconductor chip 120 is mounted. For example, the first redistribution structure 110 may include a first redistribution pattern 113, and a first redistribution insulating layer 111 that covers or surrounds the first redistribution pattern 113.

Hereinafter, a direction parallel to an upper surface of the first redistribution structure 110 facing the first semiconductor chip 120 is defined as a horizontal direction (for example, an X direction and/or a Y direction), a direction perpendicular to the upper surface of the first redistribution structure 110 is defined as a vertical direction (for example, a Z direction), and a horizontal width is defined as a distance in the horizontal direction (for example, the X direction and/or the Y direction).

The first redistribution insulating layer 111 may be formed of a material film including an organic compound. The first redistribution insulating layer 111 may include an insulating material including a photo imageable dielectric (PID) material. For example, the first redistribution insulating layer 111 may include a photosensitive polyimide (PSPI). The first redistribution insulating layer 111 may include a plurality of insulating layers stacked in the vertical direction (for example, the Z direction), or a single insulating layer.

The first redistribution pattern 113 may include a plurality of first redistribution conductive layers 1131 extending in the horizontal direction (for example, the X direction and/or the Y direction), and a plurality of first redistribution vias 1133 extending to at least partially pass through the first redistribution insulating layer 111. The plurality of first redistribution conductive layers 1131 may extend along at least one of respective upper and lower surfaces of the insulating layers constituting the first redistribution insulating layer 111. The plurality of first redistribution vias 1133 may electrically connect the first redistribution conductive layers 1131, which are located at different levels from each other in the vertical direction (for example, the Z direction), to each other. In some embodiments, each of the plurality of first redistribution vias 1133 may have a tapered shape having a decreasing horizontal width toward the upper surface of the first redistribution structure 110. For example, the first redistribution pattern 113 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. A seed metal layer may be arranged between the first redistribution pattern 113 and the first redistribution insulating layer 111.

The first redistribution conductive layers 1131 provided on an upper surface of the first redistribution insulating layer 111 may include a first upper redistribution pad 114, a first redistribution bonding pad 116, and a second redistribution bonding pad 117. In a cross-sectional view, each of the first upper redistribution pad 114, the first redistribution bonding pad 116, and the second redistribution bonding pad 117 may have a rectangular shape. In addition, the first redistribution conductive layers 1131 provided on a lower surface of the first redistribution insulating layer 111 may include a first lower redistribution pad 115. The semiconductor package 1000 may further include an external connection terminal 171 attached onto a lower surface of the first redistribution structure 110. The external connection terminal 171 may be attached to the first lower redistribution pad 115 of the first redistribution structure 110. The external connection terminal 171 may include, for example, a solder. The external connection terminal 171 may physically and electrically connect an external device with the semiconductor package 1000.

The first semiconductor chip 120 may be mounted on the first redistribution structure 110. In some embodiments, the first semiconductor chip 120 may be physically and electrically connected to the first redistribution pattern 113 of the first redistribution structure 110 via a first conductive connection pillar 141. An upper portion of the first conductive connection pillar 141 may be connected to a first lower connection pad 125 provided on a lower surface of the first semiconductor chip 120, and a lower portion of the first conductive connection pillar 141 may be connected to the first upper redistribution pad 114 of the first redistribution structure 110. The first conductive connection pillar 141 may have a pillar shape extending from the first lower connection pad 125 of the first semiconductor chip 120 to the first upper redistribution pad 114 of the first redistribution structure 110. For example, the first conductive connection pillar 141 may include copper (Cu).

The second semiconductor chip 130 may be stacked on the first semiconductor chip 120. The second semiconductor chip 130 may be physically and electrically connected to the first semiconductor chip 120 via an inter-chip connection bump 145. The inter-chip connection bump 145 may be arranged between a second lower connection pad 135 provided on a lower surface of the second semiconductor chip 130 and a first upper connection pad 126 provided on an upper surface of the first semiconductor chip 120 and may electrically connect the second lower connection pad 135 of the second semiconductor chip 130 with the first upper connection pad 126 of the first semiconductor chip 120. For example, the inter-chip connection bump 145 may include a solder.

In some embodiments, the semiconductor package 1000 may include a second conductive connection pillar 143 attached to the second lower connection pad 135 of the second semiconductor chip 130. The second conductive connection pillar 143 may have a pillar shape extending downwards from the second lower connection pad 135 of the second semiconductor chip 130. The second conductive connection pillar 143 may physically and electrically connect the second lower connection pad 135 of the second semiconductor chip 130 with the inter-chip connection bump 145, and the first semiconductor chip 120 and the second semiconductor chip 130 may be physically and electrically connected to each other via the second conductive connection pillar 143 and the inter-chip connection bump 145. An upper portion of the second conductive connection pillar 143 may be connected to the second lower connection pad 135 of the second semiconductor chip 130, and a lower portion of the second conductive connection pillar 143 may be connected to the inter-chip connection bump 145. The inter-chip connection bump 145 may partially cover or surround a sidewall of the second conductive connection pillar 143. The second conductive connection pillar 143 may include a material that is different from a material of the inter-chip connection bump 145. For example, the second conductive connection pillar 143 may include copper (Cu).

In some embodiments, the footprint of the second semiconductor chip 130 may be greater than the footprint of the first semiconductor chip 120. In some embodiments, a second horizontal width of the second semiconductor chip 130 may be greater than a first horizontal width of the first semiconductor chip 120. A central portion of the second semiconductor chip 130 may vertically overlap the first semiconductor chip 120, and an outer portion of the second semiconductor chip 130 may laterally protrude or be horizontally offset from a sidewall of the first semiconductor chip 120. The first semiconductor chip 120 may not be arranged between the outer portion of the second semiconductor chip 130 and the first redistribution structure 110, and the outer portion of the second semiconductor chip 130 may directly face or vertically overlap the first redistribution structure 110. A bonding pad 137 may be provided on a lower surface of the outer portion of the second semiconductor chip 130.

In some embodiments, each of the first semiconductor chip 120 and the second semiconductor chip 130 may include a logic chip and/or a memory chip. The logic chip may include a central processing unit (CPU) chip, a graphics processing unit (GPU) chip, an application processor (AP) chip, and an application specific integrated circuit (ASIC) chip. The memory chip may include a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip. The first semiconductor chip 120 and the second semiconductor chip 130 may include the same types of semiconductor chips or different types of semiconductor chips, respectively. In some embodiments, each of the first semiconductor chip 120 and the second semiconductor chip 130 may include a logic chip. In some embodiments, one of the first semiconductor chip 120 and the second semiconductor chip 130 may include a logic chip, and the other may include a memory chip. In some embodiments, the first semiconductor chip 120 and the second semiconductor chip 130 may respectively include chiplets configured to perform different functions from each other and may be respectively referred to as a first chiplet and a second chiplet. The first chiplet and the second chiplet may be electrically connected to each other to operate as one logic chip.

The molding layer 151 may be arranged on the first redistribution structure 110 and cover or surround at least a portion of the first semiconductor chip 120 and at least a portion of the second semiconductor chip 130. The molding layer 151 may extend along a sidewall, an upper surface, and a lower surface of the first semiconductor chip 120 and at least partially cover the sidewall, the upper surface, and the lower surface of the first semiconductor chip 120. The molding layer 151 may extend along a sidewall and a lower surface of the second semiconductor chip 130 and at least partially cover the sidewall and the lower surface of the second semiconductor chip 130. The molding layer 151 may not cover an upper surface of the second semiconductor chip 130. In some embodiments, an upper surface of the molding layer 151 and the upper surface of the second semiconductor chip 130 may be coplanar with each other. The molding layer 151 may be in or fill a gap between the first semiconductor chip 120 and the first redistribution structure 110 and surround a sidewall of the first conductive connection pillar 141. The molding layer 151 may be in or fill a gap between the first semiconductor chip 120 and the second semiconductor chip 130 and surround a sidewall of the inter-chip connection bump 145 and a sidewall of the second conductive connection pillar 143. The molding layer 151 may include an insulating polymer or an epoxy resin. For example, the molding layer 151 may include an epoxy mold compound (EMC).

The second redistribution structure 160 may be arranged on the second semiconductor chip 130 and the molding layer 151. The second redistribution structure 160 may directly contact the upper surface of the second semiconductor chip 130 and the upper surface of the molding layer 151. The second redistribution structure 160 may include a second redistribution pattern 163 and a second redistribution insulating layer 161 that covers or surrounds the second redistribution pattern 163.

The second redistribution insulating layer 161 may be formed of a material film including an organic compound. The second redistribution insulating layer 161 may include a PID or a PSPI. The material of the second redistribution insulating layer 161 may be the same as the material of the first redistribution insulating layer 111. The second redistribution insulating layer 161 may include a plurality of insulating layers stacked in the vertical direction (for example, the Z direction).

The second redistribution pattern 163 may include a plurality of second redistribution conductive layers 1631 extending in the horizontal direction (for example, the X direction and/or the Y direction), and a plurality of second redistribution vias 1633 extending to at least partially pass through the second redistribution insulating layer 161. The plurality of second redistribution conductive layers 1631 may extend along at least one of respective upper and lower surfaces of the insulating layers constituting the second redistribution insulating layer 161. The plurality of second redistribution vias 1633 may electrically connect the second redistribution conductive layers 1631, which are located at different levels from each other in the vertical direction (for example, the Z direction), to each other. In some embodiments, each of the plurality of second redistribution vias 1633 may have a tapered shape having a decreasing horizontal width toward the upper surface of the second redistribution structure 160 (or away from the lower surface of the second redistribution structure 160). The material of the second redistribution pattern 163 may be the same as the material of the first redistribution pattern 113. A seed metal layer may be arranged between the second redistribution pattern 163 and the second redistribution insulating layer 161. The plurality of second redistribution conductive layers 1631 may include a second upper redistribution pad 164 provided on an upper surface of the second redistribution insulating layer 161, and a third redistribution bonding pad 166 provided on a lower surface of the second redistribution insulating layer 161. An electronic component (for example, a semiconductor package, a semiconductor chip, a passive component, or the like) may be mounted on the second redistribution structure 160. In a cross-sectional view, the second upper redistribution pad 164 may have a rectangular shape. An upper surface of the second upper redistribution pad 164 may be substantially coplanar with the upper surface of the second redistribution insulating layer 161. A connection terminal for connecting the second redistribution structure 160 to the electronic component may be attached onto the second upper redistribution pad 164.

In some embodiments, the sidewall of the first redistribution structure 110, the sidewall of the molding layer 151, and the sidewall of the second redistribution structure 160 may be aligned with each other in the vertical direction (for example, the Z direction) and may be coplanar with each other. In some embodiments, the first redistribution structure 110, the molding layer 151, and the second redistribution structure 160 may respectively have footprints that overlap each other or are equal to each other. The footprint of the first redistribution structure 110 may be greater than the footprint of the footprint of the first semiconductor chip 120 and the footprint of the second semiconductor chip 130. In some embodiments, the first redistribution structure 110, the molding layer 151, and the second redistribution structure 160 may respectively have third horizontal widths that are equal to each other. The third horizontal width of the first redistribution structure 110 may be greater than the first horizontal width of the first semiconductor chip 120 and the second horizontal width of the second semiconductor chip 130.

The first vertical connection conductor 153 may vertically pass through the molding layer 151 and extend from the first redistribution structure 110 to the second redistribution structure 160. A lower end portion of the first vertical connection conductor 153 may be directly connected to the first redistribution bonding pad 116 of the first redistribution structure 110, and an upper end portion of the first vertical connection conductor 153 may be directly connected to the third redistribution bonding pad 166 of the second redistribution structure 160. For example, the first vertical connection conductor 153 may include copper (Cu), silver (Ag), gold (Au), and/or aluminum (Al). In some embodiments, the first vertical connection conductor 153 may include a vertical connection wire, which is formed by a wire bonding process. In some embodiments, the first vertical connection conductor 153 may include a conductive post, which is formed by a plating process.

The second vertical connection conductor 155 may vertically pass through the molding layer 151 and extend from the first redistribution structure 110 to the second semiconductor chip 130. A lower end portion of the second vertical connection conductor 155 may be directly connected to the second redistribution bonding pad 117 of the first redistribution structure 110, and an upper end portion of the second vertical connection conductor 155 may be directly connected to the bonding pad 137 of the second semiconductor chip 130. For example, the second vertical connection conductor 155 may include copper (Cu), silver (Ag), gold (Au), and/or aluminum (Al). In some embodiments, the second vertical connection conductor 155 may include a vertical connection wire, which is formed by a wire bonding process. In some embodiments, the second vertical connection conductor 155 may include a conductive post, which is formed by a plating process.

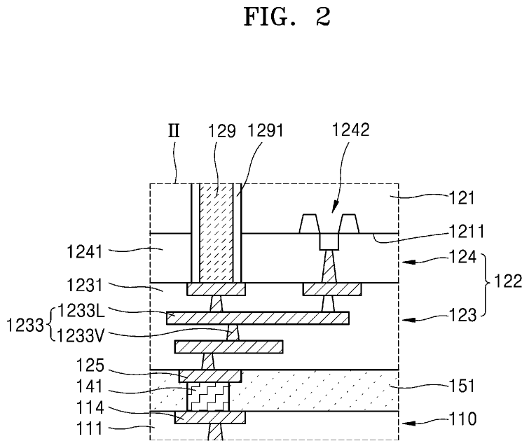

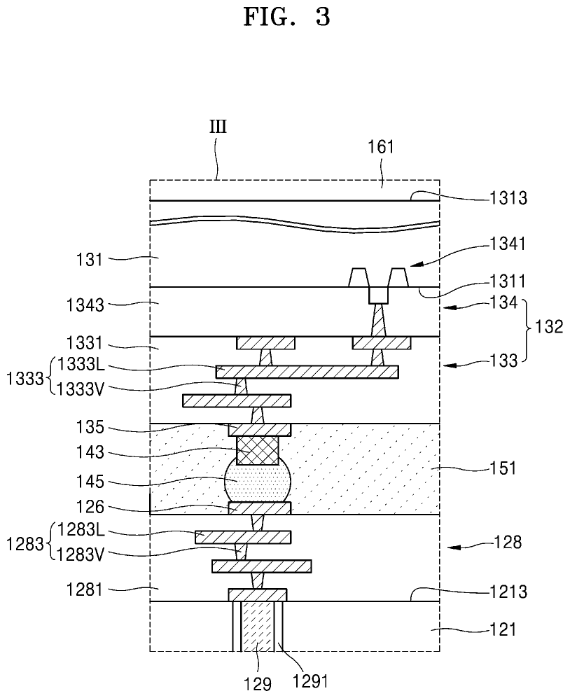

FIG. 2 is an enlarged view illustrating a region II of FIG. 1. FIG. 3 is an enlarged view illustrating a region III of FIG. 1.

Referring to FIGS. 1 to 3, the first semiconductor chip 120 may include a first semiconductor substrate 121, a first active layer 122, a first backside interconnect structure 128, and a first through-electrode 129.

The first semiconductor substrate 121 may include a first active surface 1211 and a first inactive surface 1213, which are opposite to each other. The first active surface 1211 of the first semiconductor substrate 121 may correspond to a lower surface of the first semiconductor substrate 121, which faces the first redistribution structure 110, and the first inactive surface 1213 of the first semiconductor substrate 121 may correspond to an upper surface of the first semiconductor substrate 121, which faces the second semiconductor chip 130.

The first semiconductor substrate 121 may be formed of a semiconductor wafer. The first semiconductor substrate 121 may include, for example, silicon (Si). Alternatively, the first semiconductor substrate 121 may include a semiconductor element, such as germanium (Ge), or a compound semiconductor, such as silicon carbide (SiC), gallium arsenide (GaAs), indium arsenide (InAs), and indium phosphide (InP). The first semiconductor substrate 121 may include a conductive region, for example, an impurity-doped well or an impurity-doped structure. In addition, the first semiconductor substrate 121 may have various device isolation structures, such as a shallow trench isolation (STI) structure.

The first active layer 122 may be formed on the first active surface 1211 of the first semiconductor substrate 121. The first active layer 122 may include a circuit pattern, a discrete device such as a transistor, and the like. The first active layer 122 may include a first front-end-of-line (FEOL) structure 124 arranged on the first active surface 1211 of the first semiconductor substrate 121, and a first interconnect structure 123 arranged on the first FEOL structure 124.

The first FEOL structure 124 may include a first insulating layer 1241 and various first discrete devices 1242. The first insulating layer 1241 may be arranged on the first active surface 1211 of the first semiconductor substrate 121. The first insulating layer 1241 may include a plurality of interlayer dielectrics, which are sequentially stacked on the first active surface 1211 of the first semiconductor substrate 121. The first discrete devices 1242 may be formed in the first semiconductor substrate 121 and/or on the first active surface 1211 of the first semiconductor substrate 121. The first discrete devices 1242 may include, for example, a transistor. The first discrete devices 1242 may include microelectronic devices, for example, a metal-oxide-semiconductor field effect transistor (MOSFET), a system large-scale integration (LSI), an image sensor such as a CMOS imaging sensor (CIS), a micro-electro-mechanical system (MEMS), an active element, a passive element, and the like. The first discrete devices 1242 may be electrically connected to the conductive region of the first semiconductor substrate 121. Each of the first discrete devices 1242 may be electrically isolated from other first discrete devices 1242 adjacent thereto by the first insulating layer 1241.

The first interconnect structure 123 may include a back-end-of-line (BEOL) structure, which is formed on the first FEOL structure 124. The footprint of the first interconnect structure 123 may be equal to the footprint of the first FEOL structure 124 and the footprint of the first semiconductor substrate 121. The first interconnect structure 123 may include a first interconnect insulating layer 1231, and a first interconnect pattern 1233 covered or surrounded by the first interconnect insulating layer 1231. The first interconnect pattern 1233 may be electrically connected to the first discrete devices 1242 and the conductive region of the first semiconductor substrate 121. The first interconnect pattern 1233 may include a plurality of first conductive layers 1233L extending in the horizontal direction (for example, the X direction and/or the Y direction), and a plurality of first vias 1233V extending to at least partially pass through the first interconnect insulating layer 1231. The plurality of first conductive layers 1233L may include the first lower connection pad 125 provided on a lower surface of the first interconnect insulating layer 1231. The plurality of first vias 1233V may electrically connect the first conductive layers 1233L, which are located at different levels from each other in the vertical direction (for example, the Z direction), to each other. In some embodiments, each of the plurality of first vias 1233V may have a tapered shape having a decreasing horizontal width toward the first active surface 1211 of the first semiconductor substrate 121. For example, the first interconnect pattern 1233 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

The first backside interconnect structure 128 may be arranged on the first inactive surface 1213 of the first semiconductor substrate 121. The footprint of the first backside interconnect structure 128 may be equal to the footprint of the first semiconductor substrate 121. The first backside interconnect structure 128 may include a first backside interconnect insulating layer 1281, and a first backside interconnect pattern 1283 covered or surrounded by the first backside interconnect insulating layer 1281. The first backside interconnect pattern 1283 may include a plurality of first backside conductive layers 1283L extending in the horizontal direction (for example, the X direction and/or the Y direction), and a plurality of first backside vias 1283V extending to at least partially pass through the first backside interconnect insulating layer 1281. The plurality of first backside conductive layers 1283L may include the first upper connection pad 126 provided on an upper surface of the first backside interconnect insulating layer 1281. The plurality of first backside vias 1283V may electrically connect the first backside conductive layers 1283L, which are located at different levels from each other in the vertical direction (for example, the Z direction), to each other. In some embodiments, each of the plurality of first backside vias 1283V may have a tapered shape having a decreasing horizontal width toward the first inactive surface 1213 of the first semiconductor substrate 121. For example, the material of the first backside interconnect pattern 1283 may be substantially identical or similar to the material of the first interconnect pattern 1233.

The first through-electrode 129 may vertically pass through the first semiconductor substrate 121. The first through-electrode 129 may electrically connect the first interconnect pattern 1233 of the first interconnect structure 123 with the first backside interconnect pattern 1283 of the first backside interconnect structure 128. The first through-electrode 129 may be provided to the inside of a through-hole of the first semiconductor substrate 121, and a via insulating layer 1291 may be arranged between the first through-electrode 129 and the first semiconductor substrate 121. For example, the first through-electrode 129 may include a conductive plug having a pillar shape, and a conductive barrier layer surrounding a sidewall of the conductive plug. The conductive plug may include, for example, at least one material selected from among copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru). The conductive barrier layer may include at least one material selected from among titanium (Ti), titanium nitride (TiN), tantalum (Ta), tantalum nitride (TaN), tungsten (W), tungsten nitride (WN), ruthenium (Ru), and cobalt (Co).

The second semiconductor chip 130 may include a second semiconductor substrate 131 and a second active layer 132.

The second semiconductor substrate 131 may include a second active surface 1311 and a second inactive surface 1313, which are opposite to each other. The second active surface 1311 of the second semiconductor substrate 131 may correspond to a lower surface of the second semiconductor substrate 131, which faces the first semiconductor chip 120, and the second inactive surface 1313 of the second semiconductor substrate 131 may correspond to an upper surface of the second semiconductor substrate 131, which faces the second redistribution structure 160. The material of the second semiconductor substrate 131 may be substantially identical or similar to the material of the first semiconductor substrate 121. The second semiconductor substrate 131 may include a conductive region, for example, an impurity-doped well or an impurity-doped structure. In addition, the second semiconductor substrate 131 may have various device isolation structures, such as an STI structure.

The second active layer 132 may be formed on the second active surface 1311 of the second semiconductor substrate 131. The second active layer 132 may include a circuit pattern, a discrete device such as a transistor, and the like. The second active layer 132 may include a second FEOL structure 134 arranged on the second active surface 1311 of the second semiconductor substrate 131, and a second interconnect structure 133 arranged on the second FEOL structure 134.

The second FEOL structure 134 may include a second insulating layer 1343 and various second discrete devices 1341. The second insulating layer 1343 may be arranged on the second active surface 1311 of the second semiconductor substrate 131. The second insulating layer 1343 may include a plurality of interlayer dielectrics that are sequentially stacked on the second active surface 1311 of the second semiconductor substrate 131. The second discrete devices 1341 may be formed in the second semiconductor substrate 131 and/or on the second active surface 1311 of the second semiconductor substrate 131. The second discrete devices 1341 may include, for example, a transistor. The second discrete devices 1341 may include microelectronic devices, for example, a MOSFET, a system LSI, an image sensor such as a CIS, a MEMS, an active element, a passive element, and the like. The second discrete devices 1341 may be electrically connected to the conductive region of the second semiconductor substrate 131. Each of the second discrete devices 1341 may be electrically isolated from other second discrete devices 1341 adjacent thereto by the second insulating layer 1343.

The second interconnect structure 133 may include a BEOL structure, which is formed on the second FEOL structure 134. The footprint of the second interconnect structure 133 may be equal to the footprint of the second FEOL structure 134 and the footprint of the second semiconductor substrate 131. The second interconnect structure 133 may include a second interconnect insulating layer 1331, and a second interconnect pattern 1333 covered or surrounded by the second interconnect insulating layer 1331. The second interconnect pattern 1333 may be electrically connected to the second discrete devices 1341 and the conductive region of the second semiconductor substrate 131. The second interconnect pattern 1333 may include a plurality of second conductive layers 1333L extending in the horizontal direction (for example, the X direction and/or the Y direction), and a plurality of second vias 1333V extending to at least partially pass through the second interconnect insulating layer 1331. The plurality of second conductive layers 1333L may include the second lower connection pad 135 provided on a lower surface of the second interconnect insulating layer 1331. The plurality of second vias 1333V may electrically connect the second conductive layers 1333L, which are located at different levels from each other in the vertical direction (for example, the Z direction), to each other. In some embodiments, each of the plurality of second vias 1333V may have a tapered shape having a decreasing horizontal width toward the second active surface 1311 of the second semiconductor substrate 131. The material of the second interconnect pattern 1333 may be substantially identical or similar to the material of the first interconnect pattern 1233.

The first semiconductor chip 120 may be configured to transmit electrical signals to and receive electrical signals from an external device via the first redistribution structure 110 and the first conductive connection pillar 141. In some embodiments, an input-output data signal between the first semiconductor chip 120 and the external device may be transferred via the first redistribution pattern 113 and the first conductive connection pillar 141. In some embodiments, a power signal (for example, a power supply signal and/or a ground signal) between the first semiconductor chip 120 and the external device may be transferred via the first redistribution pattern 113 and the first conductive connection pillar 141.

The second semiconductor chip 130 may be configured to transmit electrical signals to and receive electrical signals from an external device via the first redistribution structure 110 and the second vertical connection conductor 155. In some embodiments, an input-output data signal between the second semiconductor chip 130 and the external device may be transferred via the first redistribution pattern 113 and the second vertical connection conductor 155. In some embodiments, a power signal (for example, a power supply signal and/or a ground signal) between the second semiconductor chip 130 and the external device may be transferred via the second redistribution pattern 163 and the second vertical connection conductor 155. In addition, the second semiconductor chip 130 may be electrically connected with the first semiconductor chip 120 via the second conductive connection pillar 143, the inter-chip connection bump 145, and the first through-electrode 129. That is, an electrical signal between the first semiconductor chip 120 and the second semiconductor chip 130 may be transmitted via a signal transfer path that includes the second conductive connection pillar 143, the inter-chip connection bump 145, and the first through-electrode 129.

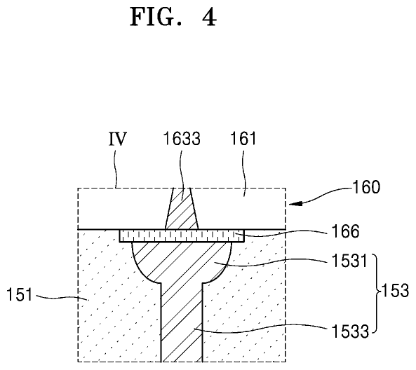

FIG. 4 is an enlarged view illustrating a region IV of FIG. 1.

Referring to FIGS. 1 and 4, the first vertical connection conductor 153 may include a vertical connection wire extending from the second redistribution structure 160 to the first redistribution structure 110 in the vertical direction (for example, the Z direction). The vertical connection wire may be formed by a wire bonding process, for example, a thermocompression wire bonding process, an ultrasonic wire bonding process, or a thermersonic wire bonding process.

When the first vertical connection conductor 153 is formed by a wire bonding process, a bonding portion 1531, which is bonded to the third redistribution bonding pad 166, is formed first by using a capillary for supplying a conductive wire, and then, a wire portion 1533, which extends in the vertical direction, is formed by moving the capillary. The bonding portion 1531 at an end of the first vertical connection conductor 153 may have a profile of a ball shape or a curve shape such as a hemispherical shape. For example, in a cross-sectional view, the bonding portion 1531 at the end of the first vertical connection conductor 153 may have a laterally convex shape. The wire portion 1533 may extend with a uniform width and have a profile of a straight-line shape. Therefore, an upper end portion of the first vertical connection conductor 153, which is bonded to the third redistribution bonding pad 166, may have a shape having a decreasing horizontal width away from the third redistribution bonding pad 166. In addition, other portions of the first vertical connection conductor 153 except for the upper end portion thereof may have a line shape having a substantially constant width. The contact area between the first vertical connection conductor 153 and the third redistribution bonding pad 166 may be greater than the contact area between the first vertical connection conductor 153 and the first redistribution bonding pad 116.

In general, when a vertical connection conductor is formed by a plating process, a seed metal layer and/or an adhesive metal layer (for example, a Ti layer) is arranged between the vertical connection conductor and a pad. However, when the first vertical connection conductor 153 includes a vertical connection wire formed by a wire bonding process, any other metal layer may not be arranged between the first vertical connection conductor 153 and the third redistribution bonding pad 166, and the first vertical connection conductor 153 may be directly connected to the third redistribution bonding pad 166.

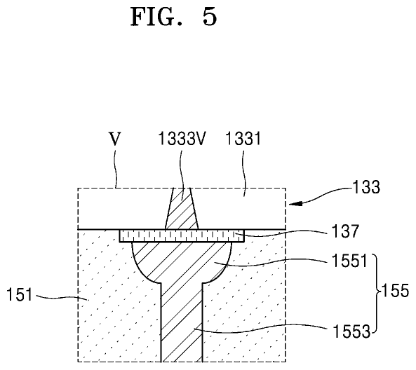

FIG. 5 is an enlarged view illustrating a region V of FIG. 1.

Referring to FIGS. 1 and 5, the second vertical connection conductor 155 may include a vertical connection wire extending from the outer portion of the second semiconductor chip 130 to the first redistribution structure 110 in the vertical direction (for example, the Z direction). The vertical connection wire may be formed by a wire bonding process, for example, a thermocompression wire bonding process, an ultrasonic wire bonding process, or a thermersonic wire bonding process.

When the second vertical connection conductor 155 is formed by a wire bonding process, a bonding portion 1551, which is bonded to the bonding pad 137 of the second semiconductor chip 130, is formed first by using a capillary for supplying a conductive wire, and then, a wire portion 1553, which extends in the vertical direction, is formed by moving the capillary. The bonding portion 1551 at an end of the second vertical connection conductor 155 may have a profile of a ball shape or a curve shape such as a hemispherical shape. For example, in a cross-sectional view, the bonding portion 1551 at the end of the second vertical connection conductor 155 may have a laterally convex shape. The wire portion 1553 may extend with a uniform width and have a profile of a straight-line shape. Therefore, an upper end portion of the second vertical connection conductor 155, which is bonded to the bonding pad 137 of the second semiconductor chip 130, may have a shape having a decreasing horizontal width away from the bonding pad 137 of the second semiconductor chip 130. In addition, other portions of the second vertical connection conductor 155 except for the upper end portion thereof may have a line shape having a substantially constant width. The contact area between the second vertical connection conductor 155 and the bonding pad 137 of the second semiconductor chip 130 may be greater than the contact area between the second vertical connection conductor 155 and the second redistribution bonding pad 117. When the second vertical connection conductor 155 includes a vertical connection wire formed by a wire bonding process, any other metal layer may not be arranged between the second vertical connection conductor 155 and the bonding pad 137 of the second semiconductor chip 130, and the second vertical connection conductor 155 may be directly connected to the bonding pad 137 of the second semiconductor chip 130.

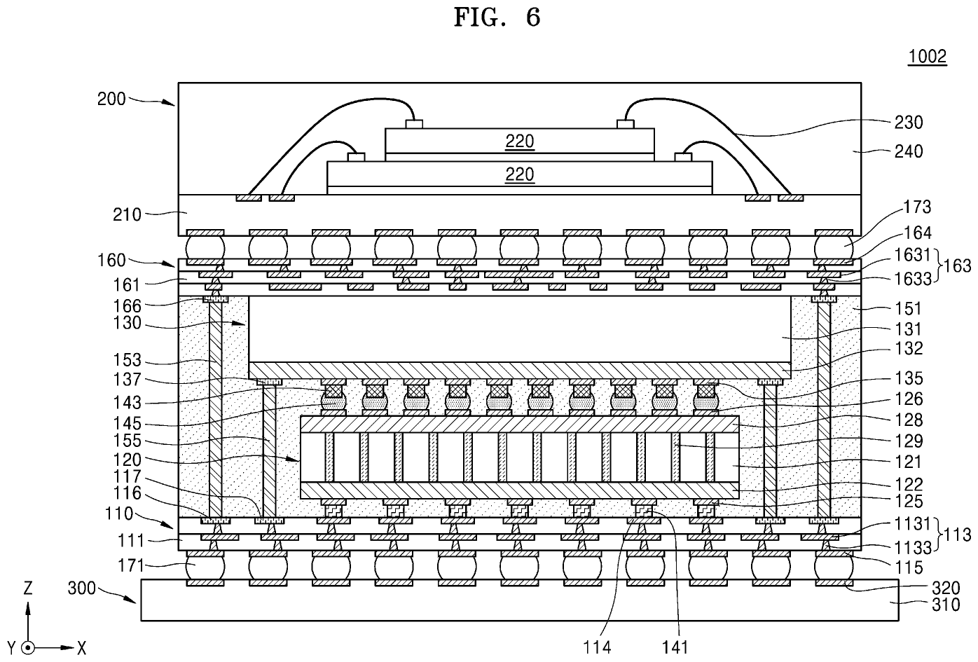

FIG. 6 is a cross-sectional view illustrating a semiconductor package 1002 according to some embodiments. Hereinafter, the semiconductor package 1002 shown in FIG. 6 will be described with the main focus on differences from the semiconductor package 1000 described with reference to FIG. 1.

Referring to FIG. 6, the semiconductor package 1002 may include an upper semiconductor device 200 arranged on the second redistribution structure 160. The upper semiconductor device 200 may be mounted on the second redistribution structure 160 via an upper connection terminal 173. A lower portion of the upper connection terminal 173 may be coupled to the second upper redistribution pad 164 of the second redistribution structure 160, and an upper portion of the upper connection terminal 173 may be coupled to the upper semiconductor device 200. The upper connection terminal 173 may electrically and physically connect the second redistribution structure 160 with the upper semiconductor device 200.

In some embodiments, the upper semiconductor device 200 may include an upper substrate 210, one or more upper semiconductor chips 220 mounted on the upper substrate 210, an upper molding layer 240 arranged on the upper substrate 210 to cover the upper semiconductor chips 220, and a conductive connection member 230 electrically connecting the upper semiconductor chips 220 with the upper substrate 210. The upper substrate 210 may include, for example, a printed circuit board. The upper semiconductor chips 220 may each include a memory chip and/or a logic chip. In some embodiments, each of the upper semiconductor chips 220 may include a memory chip, and each of the first and second semiconductor chips 120 and 130 may include a logic chip.

In some embodiments, the upper semiconductor chips 220 may be directly mounted on the second redistribution structure 160.

The first semiconductor chip 120 may be electrically connected with the upper semiconductor chips 220 via an electrical connection path, which includes the first conductive connection pillar 141, the first redistribution pattern 113, the first vertical connection conductor 153, the second redistribution pattern 163, and the upper connection terminal 173. The second semiconductor chip 130 may be electrically connected with the upper semiconductor chips 220 via an electrical connection path, which includes the second vertical connection conductor 155, the first redistribution pattern 113, the first vertical connection conductor 153, the second redistribution pattern 163, and the upper connection terminal 173.

The semiconductor package 1002 may further include a board substrate 300 arranged under the first redistribution structure 110. The board substrate 300 may include, for example, a printed circuit board. The board substrate 300 may include a core insulating layer 310, and a substrate pad 320 arranged on the core insulating layer 310. An external connection terminal 171 may be arranged between the substrate pad 320 of the board substrate 300 and the first lower redistribution pad 115 of the first redistribution structure 110 and may electrically and physically connect the substrate pad 320 of the board substrate 300 with the first lower redistribution pad 115 of the first redistribution structure 110.

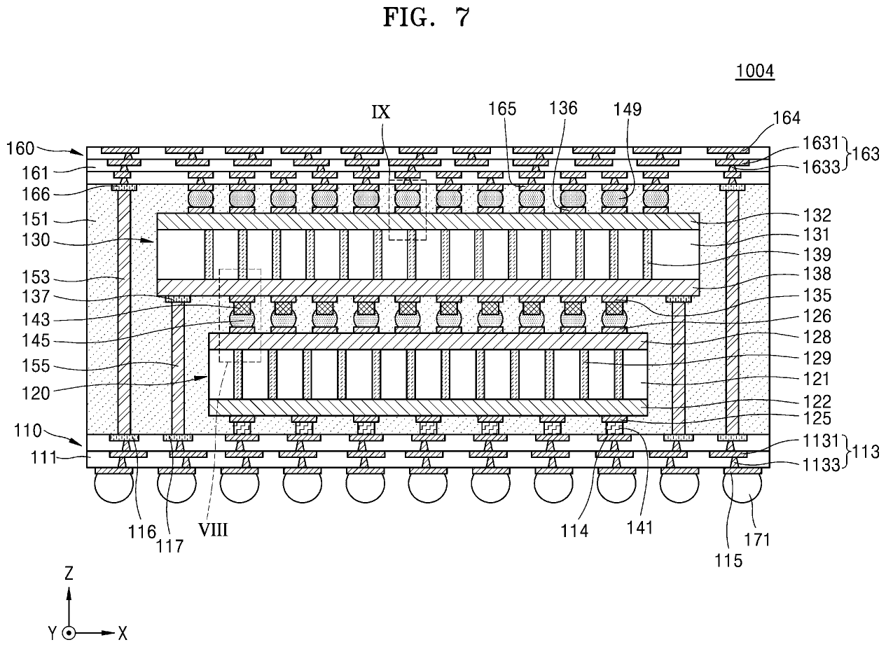

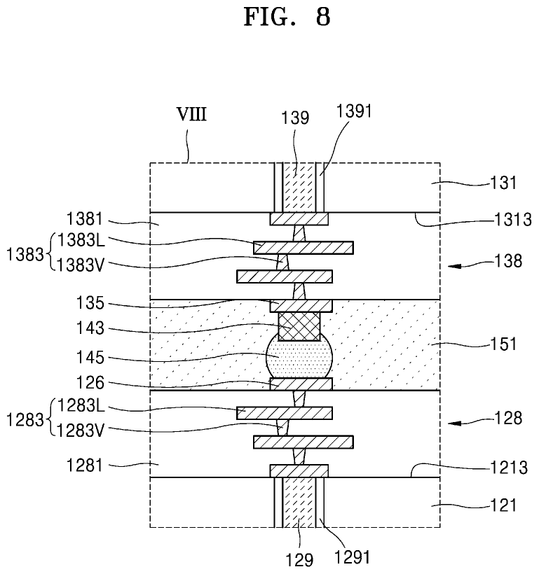

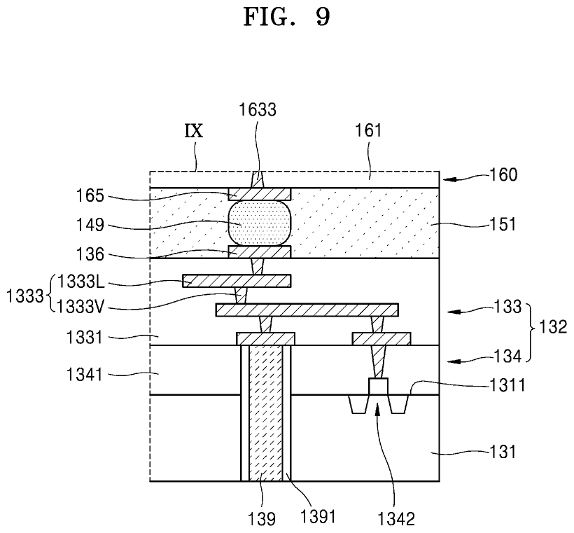

FIG. 7 is a cross-sectional view illustrating a semiconductor package 1004 according to some embodiments. FIG. 8 is an enlarged view illustrating a region VIII of FIG. 7. FIG. 9 is an enlarged view illustrating a region IX of FIG. 7. Hereinafter, the semiconductor package 1004 shown in FIGS. 7 to 9 will be described with the main focus on differences from the semiconductor package 1000 described with reference to FIG. 1.

Referring to FIGS. 7 to 9, in the semiconductor package 1004, the first semiconductor chip 120 may be arranged such that the first active layer 122 faces the first redistribution structure 110, and the second semiconductor chip 130 may be arranged such that the second active layer 132 faces the second redistribution structure 160. In the first semiconductor chip 120, the first active surface 1211 of the first semiconductor substrate 121 may face the first redistribution structure 110, and the first inactive surface 1213 of the first semiconductor substrate 121 may face the second semiconductor chip 130. In the second semiconductor chip 130, the second active surface 1311 of the second semiconductor substrate 131 may face the second redistribution structure 160, and the second inactive surface 1313 of the second semiconductor substrate 131 may face the first semiconductor chip 120.

The second semiconductor chip 130 may be electrically connected to the second redistribution structure 160 via a connection bump 149. More specifically, the second redistribution pattern 163 of the second redistribution structure 160 may include the second lower redistribution pad 165 provided on the lower surface of the second redistribution insulating layer 161, and the connection bump 149 may be arranged between the second upper connection pad 136 of the second semiconductor chip 130 and the second lower redistribution pad 165 of the second redistribution structure 160. The connection bump 149 may electrically and physically connect the second upper connection pad 136 of the second semiconductor chip 130 with the second lower redistribution pad 165 of the second redistribution structure 160. The molding layer 151 may be in or fill a gap between the second semiconductor chip 130 and the second redistribution structure 160 and surround a sidewall of the connection bump 149.

The second semiconductor chip 130 may include the second active layer 132, a second backside interconnect structure 138, and a second through-electrode 139.

The second active layer 132 may include the second FEOL structure 134 on the second active surface 1311 of the second semiconductor substrate 131, and the second interconnect structure 133 on the second FEOL structure 134. The second interconnect pattern 1333 of the second interconnect structure 133 may include the second upper connection pad 136 arranged on the second interconnect insulating layer 1331.

The second backside interconnect structure 138 may be arranged on the second inactive surface 1313 of the second semiconductor substrate 131. The footprint of the second backside interconnect structure 138 may be equal to the footprint of the second semiconductor substrate 131. The second backside interconnect structure 138 may include a second backside interconnect insulating layer 1381, and a second backside interconnect pattern 1383 covered or surrounded by the second backside interconnect insulating layer 1381. The second backside interconnect pattern 1383 may include a plurality of second backside conductive layers 1383L extending in the horizontal direction (for example, the X direction and/or the Y direction), and a plurality of second backside vias 1383V extending to at least partially pass through the second backside interconnect insulating layer 1381. The plurality of second backside conductive layers 1383L may include a second lower connection pad 135 provided on a lower surface of the second backside interconnect insulating layer 1381. The plurality of second backside vias 1383V may electrically connect the second backside conductive layers 1383L, which are located at different levels from each other in the vertical direction (for example, the Z direction), to each other. In some embodiments, each of the plurality of second backside vias 1383V may have a tapered shape having a decreasing horizontal width toward the second inactive surface 1313 of the second semiconductor substrate 131. For example, the material of the second backside interconnect pattern 1383 may be substantially identical or similar to the material of the second interconnect pattern 1333.

The second through-electrode 139 may vertically pass through the second semiconductor substrate 131. The second through-electrode 139 may electrically connect the second interconnect pattern 1333 of the second interconnect structure 133 with the second backside interconnect pattern 1383 of the second backside interconnect structure 138. The second through-electrode 139 may be provided to the inside of a through-hole of the second semiconductor substrate 131, and a via insulating layer 1391 may be arranged between the second through-electrode 139 and the second semiconductor substrate 131. For example, the second through-electrode 139 may include a conductive plug having a pillar shape, and a conductive barrier layer surrounding a sidewall of the conductive plug. The material of the second through-electrode 139 may be substantially identical or similar to the material of the first through-electrode 129.

In some embodiments, the first semiconductor chip 120 may be electrically connected with the second semiconductor chip 130 via an electrical connection path, which includes the first through-electrode 129, the inter-chip connection bump 145, the second conductive connection pillar 143, and the second through-electrode 139.

In some embodiments, the upper semiconductor device 200 (see FIG. 6) may be further arranged on the second redistribution structure 160. In this case, the second semiconductor chip 130 may be electrically connected to the upper semiconductor device 200 via an electrical connection path, which includes the connection bump 149 and the second redistribution pattern 163. Because the second semiconductor chip 130 and the upper semiconductor device 200 may be electrically connected to each other via the electrical connection path that is relatively short, a signal transmission speed between the second semiconductor chip 130 and the upper semiconductor device 200 (see FIG. 6) may improve.

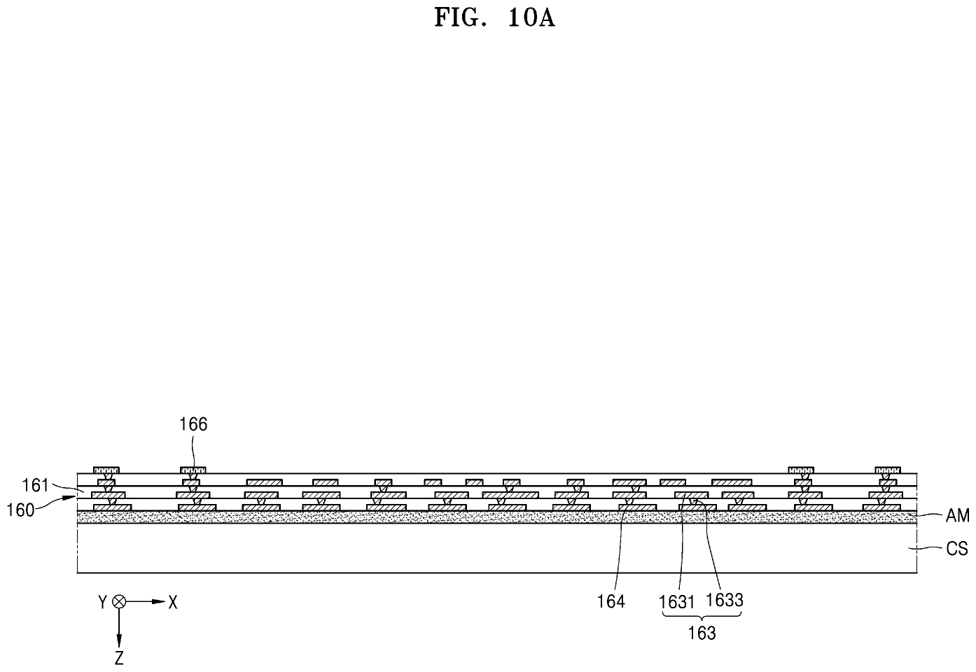

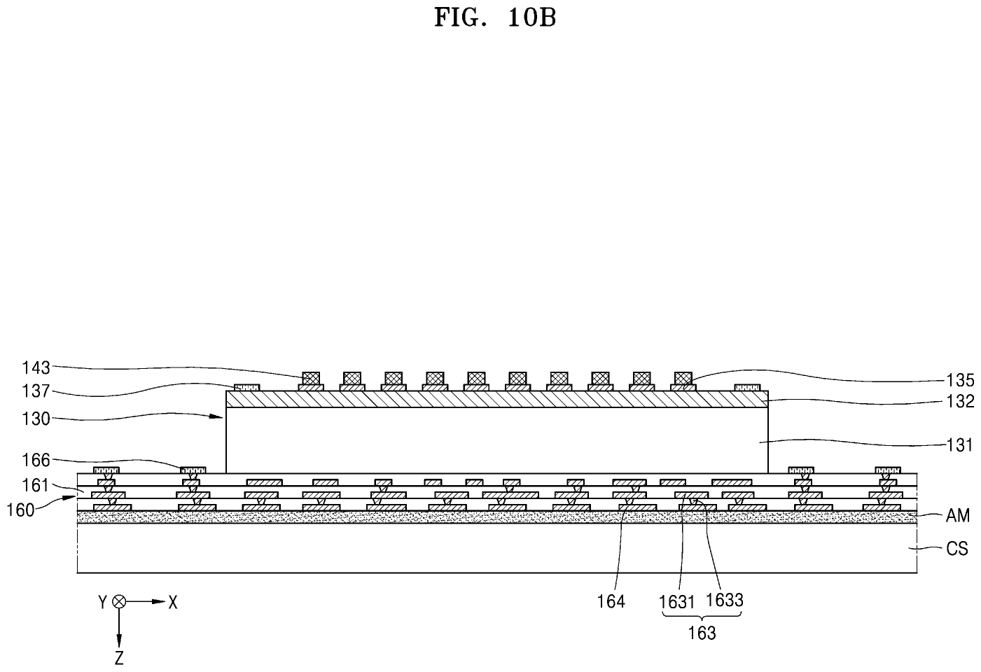

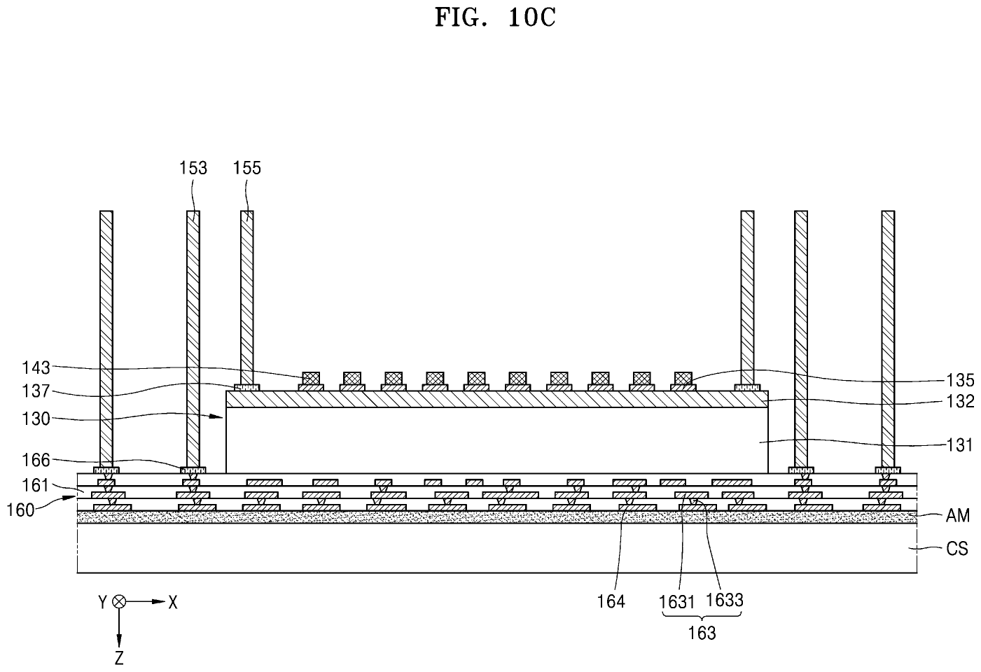

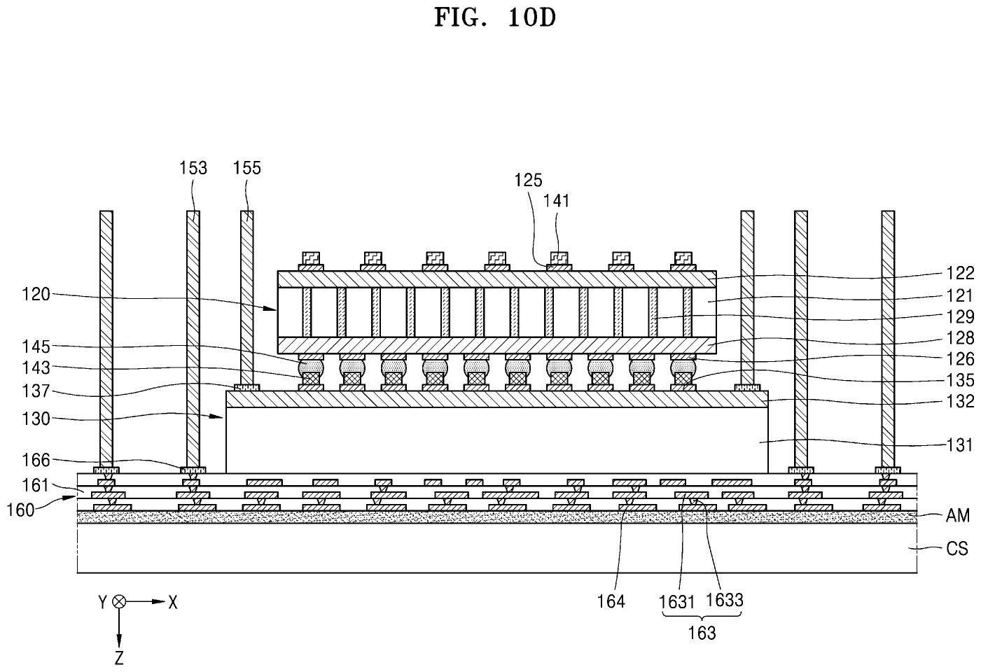

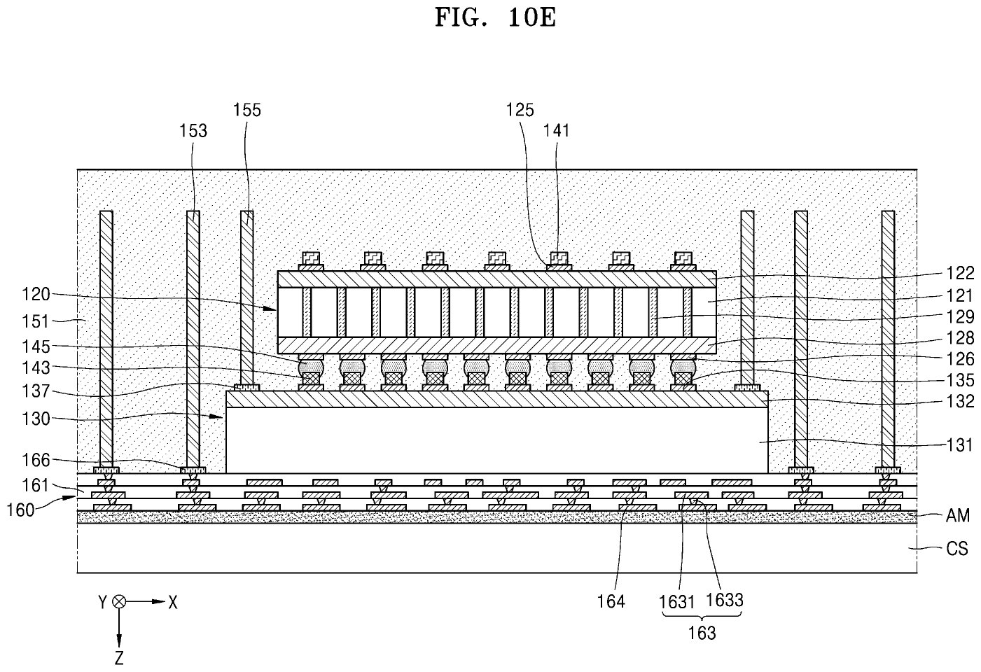

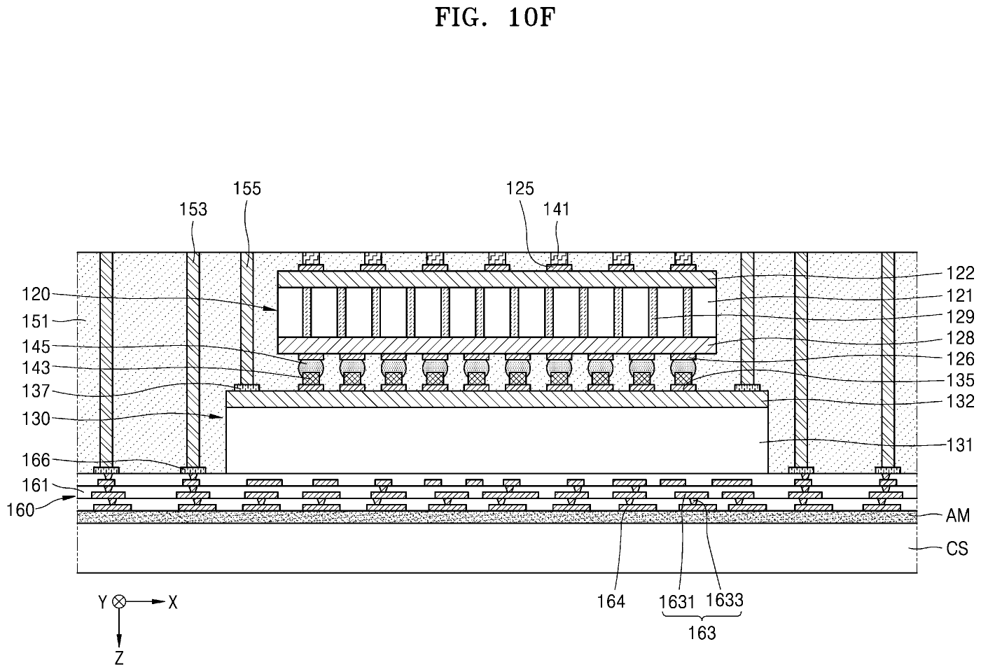

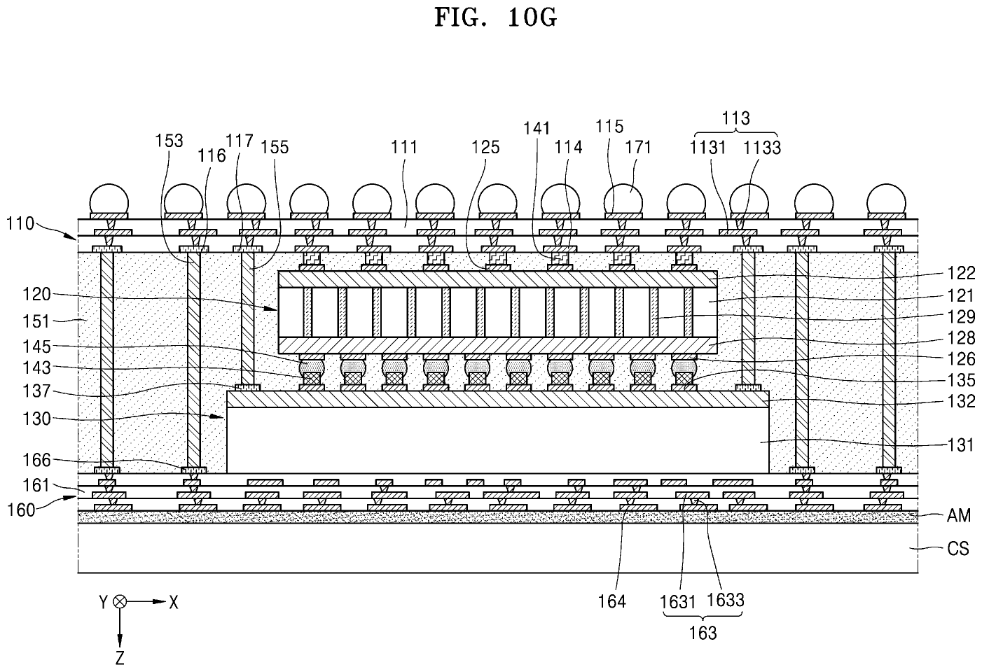

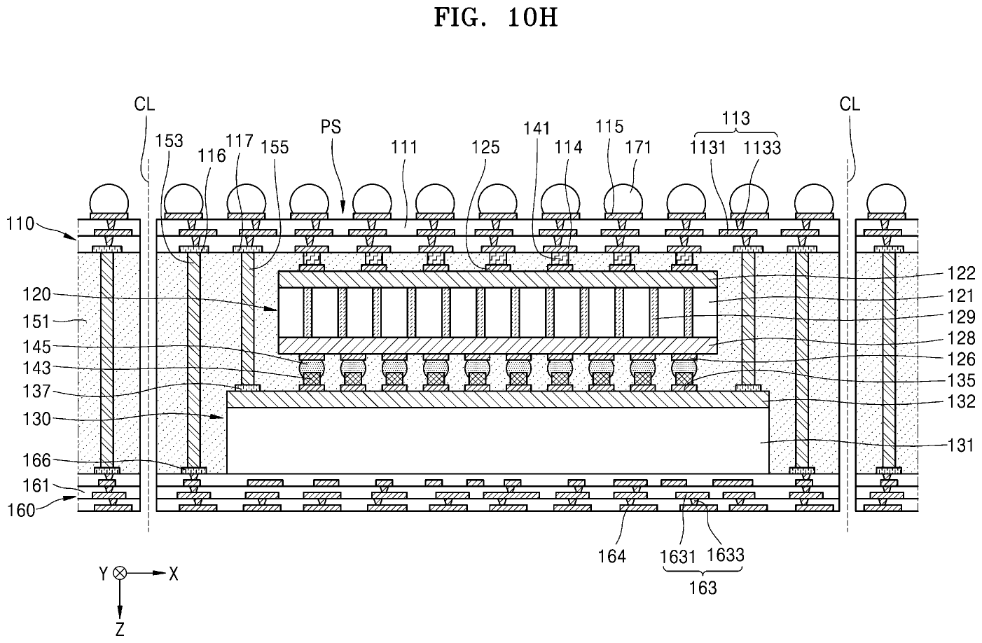

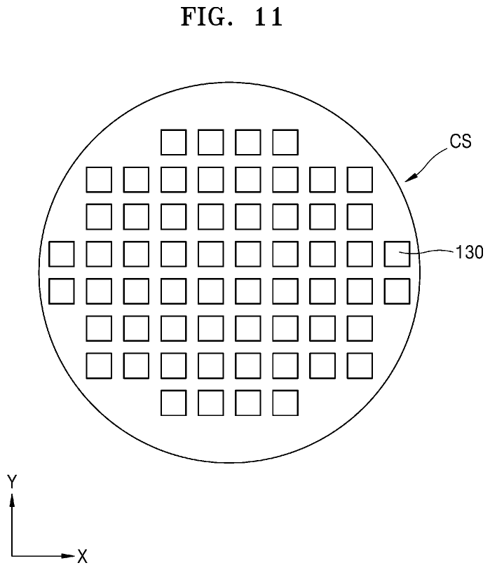

FIGS. 10A to 10H are cross-sectional views illustrating a method of manufacturing a semiconductor package, according to some embodiments. FIG. 11 is a plan view schematically illustrating a structure shown in FIG. 10B. Hereinafter, a method of manufacturing the semiconductor package 1002 described with reference to FIG. 6 will be described with reference to FIGS. 10A to 10H and 11.

Referring to FIG. 10A, a carrier substrate CS is prepared. The carrier substrate CS may have a flat plate shape. In a plan view, the carrier substrate CS may have a circular shape, or a polygonal shape such as a quadrangular shape. The carrier substrate CS may include, for example, a semiconductor substrate, a glass substrate, a ceramic substrate, or a plastic substrate. An adhesive material layer AM may be applied on the carrier substrate CS.

Next, the second redistribution structure 160 is formed on the carrier substrate CS, the second redistribution structure 160 including the second redistribution pattern 163 and the second redistribution insulating layer 161. For example, sub-insulating layers (for example, first to third sub-insulating layers) constituting the second redistribution insulating layer 161 may each be formed by a lamination process, and the second redistribution pattern 163 may be formed by a plating process. For example, forming the second redistribution structure 160 may include forming the second upper redistribution pad 164 on an upper surface of the adhesive material layer AM, forming the first sub-insulating layer to cover the second upper redistribution pad 164, forming the second redistribution via 1633 to fill a via hole of the first sub-insulating layer simultaneously with forming the second redistribution conductive layer 1631 to extend along an upper surface of the first sub-insulating layer, forming the second sub-insulating layer to cover the first sub-insulating layer, forming the second redistribution via 1633 to fill a via hole of the second sub-insulating layer simultaneously with forming the second redistribution conductive layer 1631 to extend along an upper surface of the second sub-insulating layer, forming the third sub-insulating layer to cover the second sub-insulating layer, and forming the second redistribution via 1633 to fill a via hole of the third sub-insulating layer simultaneously with forming the second redistribution conductive layer 1631 to extend along an upper surface of the third sub-insulating layer. The second redistribution conductive layer 1631 arranged on the upper surface of the third sub-insulating layer may include the third redistribution bonding pad 166.

Referring to FIG. 10B, the second semiconductor chip 130, which has the second conductive connection pillar 143, is mounted on the second redistribution structure 160. The second semiconductor chip 130 may include a known good die that is determined by a test process. As shown in FIG. 11, a large number of second semiconductor chips 130 may be relocated on the upper surface of the carrier substrate CS. The second semiconductor chip 130 may be mounted on the second redistribution structure 160 such that the second inactive surface 1313 of the second semiconductor substrate 131 faces the second redistribution structure 160. The second semiconductor chip 130 may be secured onto the second redistribution structure 160 via an adhesive film, such as a die attach film.

Referring to FIG. 10C, after the second semiconductor chip 130 is mounted on the second redistribution structure 160, the first vertical connection conductor 153 and the second vertical connection conductor 155 are respectively formed on the third redistribution bonding pad 166 of the second redistribution structure 160 and the bonding pad 137 of the second semiconductor chip 130.

In some embodiments, the first vertical connection conductor 153 and the second vertical connection conductor 155 may each be formed by a wire bonding process. To form the first vertical connection conductor 153, a bonding portion, which is directly coupled to the third redistribution bonding pad 166 of the second redistribution structure 160, may be formed first, and a wire portion, which extends in the vertical direction from the bonding portion, may be formed while moving a capillary for supplying a conductive wire, upwards. To form the second vertical connection conductor 155, a bonding portion, which is directly coupled to the bonding pad 137 of the second semiconductor chip 130, may be formed first, and a wire portion, which extends in the vertical direction from the bonding portion, may be formed while moving a capillary for supplying a conductive wire, upwards.

Referring to FIG. 10D, after the first and second vertical connection conductors 153 and 155 are formed, the first semiconductor chip 120 having the first conductive connection pillar 141 is mounted on the second semiconductor chip 130. The first semiconductor chip 120 may include a known good die that is determined by a test process. The first semiconductor chip 120 may be mounted on the second semiconductor chip 130 such that the first inactive surface 1213 of the first semiconductor substrate 121 faces the second semiconductor chip 130. The first semiconductor chip 120 may be mounted on the second semiconductor chip 130 via the inter-chip connection bump 145. Because the inter-chip connection bump 145 is coupled to the second conductive connection pillar 143, the first semiconductor chip 120 may be secured onto the second semiconductor chip 130.

Although FIGS. 10C and 10D illustrate that mounting the first semiconductor chip 120 is performed after the formation of the first and second vertical connection conductors 153 and 155 is completed, unlike this, the formation of the first and second vertical connection conductors 153 and 155 may be performed after the mounting of the first semiconductor chip 120 is completed.

Referring to FIG. 10E, after the first semiconductor chip 120 is mounted on the second semiconductor chip 130, the molding layer 151 is formed on the second redistribution structure 160. The molding layer 151 may be formed to cover the first and second semiconductor chips 120 and 130, the first and second vertical connection conductors 153 and 155, and the first conductive connection pillar 141.

Referring to FIGS. 10E and 10F, a portion of the molding layer 151 may be removed to expose the first and second vertical connection conductors 153 and 155 and the first conductive connection pillar 141. To remove the portion of the molding layer 151, a chemical mechanical polishing (CMP) process, a grinding process, and/or an etch-back process may be performed. For example, the portion of the molding layer 151, a portion of the first vertical connection conductor 153, a portion of the second vertical connection conductor 155, and a portion of the first conductive connection pillar 141 may be removed by a polishing process. In some embodiments, as a result of the polishing process, a polished surface of the molding layer 151, a polished surface of the first vertical connection conductor 153, a polished surface of the second vertical connection conductor 155, and a polished surface of the first conductive connection pillar 141 may be coplanar with each other.

Referring to FIG. 10G, the first redistribution structure 110, which includes the first redistribution pattern 113 and the first redistribution insulating layer 111, is formed on the molding layer 151. For example, sub-insulating layers (for example, fourth and fifth sub-insulating layers) constituting the first redistribution insulating layer 111 may each be formed by a lamination process, and the first redistribution pattern 113 may be formed by a plating process. For example, forming the first redistribution structure 110 may include forming the first redistribution conductive layer 1131, which is connected to the first and second vertical connection conductors 153 and 155 and the first conductive connection pillar 141, forming the fourth sub-insulating layer to cover the molding layer 151, forming the first redistribution via 1133 to fill a via hole of the fourth sub-insulating layer simultaneously with forming the first redistribution conductive layer 1131 to extend along an upper surface of the fourth sub-insulating layer, forming the fifth sub-insulating layer to cover the fourth sub-insulating layer, and forming the first redistribution via 1133 to fill a via hole of the fifth sub-insulating layer simultaneously with forming the first redistribution conductive layer 1131 to extend along an upper surface of the fifth sub-insulating layer. The first redistribution conductive layer 1131 arranged on the upper surface of the fifth sub-insulating layer may include the first lower redistribution pad 115.

After the first redistribution structure 110 is formed, the external connection terminal 171 is formed on the first lower redistribution pad 115 of the first redistribution structure 110. The external connection terminal 171 may be formed by, for example, a reflow process using a solder ball.

Referring to FIGS. 10G and 10H, after the external connection terminal 171 is formed, a detachment process for separating the carrier substrate CS from the second redistribution structure 160 is performed. For example, the adhesion of the adhesive material layer AM may be reduced by applying light and/or heat to the adhesive material layer AM, and then, the adhesive material layer AM and the carrier substrate CS may be separated from the second redistribution structure 160.

After the carrier substrate CS is separated from the second redistribution structure 160, a sawing process for cutting a panel-shaped structure, which has a size corresponding to the carrier substrate CS, along a cutting line CL may be performed. Through the sawing process, the panel-shaped structure may be separated into individual-unit packages PS.

Next, referring together to FIGS. 10H and 6, a package PS, which is cut into an individual unit, is mounted on the board substrate 300. For example, the package PS may be located on the board substrate 300 such that the external connection terminal 171 contacts the substrate pad 320 of the board substrate 300, and then, a reflow process may be performed on the external connection terminal 171. After the package PS is mounted on the board substrate 300, the upper semiconductor device 200 may be mounted on the second redistribution structure 160.

In general, when a vertical connection structure is formed by using an electrolytic plating process, to cause current to uniformly flow on the whole, in performing the electrolytic plating process, an intermediate structure on a carrier substrate is required to have a flat upper surface. In general, when vertical connection conductors having different heights from each other (that is, a long vertical connection conductor and a short vertical connection conductor) are formed by electrolytic plating processes, forming a lower portion of the long vertical connection conductor by a first electrolytic plating process, performing first molding for forming a first molding film to cover the lower portion of the long vertical connection conductor, planarizing the first molding film, forming both an upper portion of the long vertical connection conductor and the short vertical connection conductor by a second electrolytic plating process, forming a second molding film to cover the long vertical connection conductor and the short vertical connection conductor, and planarizing the second molding film are required.

However, according to some embodiments, by forming the first and second vertical connection conductors 153 and 155 having different lengths from each other through wire bonding processes, the molding layer 151, which covers the first and second semiconductor chips 120 and 130 and the first and second vertical connection conductors 153 and 155, may be formed by one molding process. Therefore, a manufacturing process of a semiconductor package may be simplified, and the manufacturing cost thereof may be reduced.

While the inventive concept has been particularly shown and described with reference to embodiments thereof, it will be understood that various changes in form and details may be made therein without departing from the scope of the following claims.

1. A semiconductor package comprising:
a first redistribution structure comprising a first redistribution pattern and a first redistribution insulating layer;
a first semiconductor chip on the first redistribution structure, the first semiconductor chip comprising a first semiconductor substrate and a first through-electrode extending through the first semiconductor substrate;
a second semiconductor chip on the first semiconductor chip, the second semiconductor chip comprising a central portion vertically overlapping the first semiconductor chip and an outer portion horizontally offset from a sidewall of the first semiconductor chip;
an inter-chip connection bump between the first semiconductor chip and the second semiconductor chip;
a molding layer in contact with the first redistribution structure, the first semiconductor chip, the second semiconductor chip, and the inter-chip connection bump;
a second redistribution structure on the second semiconductor chip and the molding layer, the second redistribution structure comprising a second redistribution pattern and a second redistribution insulating layer;
a first vertical connection wire extending through the molding layer and extending from the first redistribution structure to the second redistribution structure; and
a second vertical connection wire extending through the molding layer and extending from the first redistribution structure to the outer portion of the second semiconductor chip.

2. The semiconductor package of claim 1, wherein the first semiconductor chip has a first horizontal width in a first horizontal direction,
the second semiconductor chip has a second horizontal width in the first horizontal direction that is greater than the first horizontal width of the first semiconductor chip, and
each of the first redistribution structure and the second redistribution structure has a third horizontal width that is greater than the second horizontal width of the second semiconductor chip.

3. The semiconductor package of claim 1, wherein the first vertical connection wire comprises: a first end portion connected to a first bonding pad of the first redistribution structure; and a second end portion connected to a second bonding pad of the second redistribution structure, and
a contact area between the first vertical connection wire and the second bonding pad of the second redistribution structure is greater than a contact area between the first vertical connection wire and the first bonding pad of the first redistribution structure.

4. The semiconductor package of claim 1, wherein the second vertical connection wire comprises: a first end portion connected to a third bonding pad of the first redistribution structure; and a second end portion connected to a fourth bonding pad of the second semiconductor chip, and
a contact area between the second vertical connection wire and the fourth bonding pad of the second semiconductor chip is greater than a contact area between the second vertical connection wire and the third bonding pad of the first redistribution structure.

5. The semiconductor package of claim 1, further comprising a first conductive connection pillar extending from a first lower connection pad of the first semiconductor chip to a first redistribution pad of the first redistribution structure,
wherein a portion of the molding layer is between the first semiconductor chip and the first redistribution structure and is in contact with a sidewall of the first conductive connection pillar.

6. The semiconductor package of claim 1, further comprising a second conductive connection pillar connected to a second lower connection pad of the second semiconductor chip,
wherein the inter-chip connection bump is between the second conductive connection pillar and a first upper connection pad of the first semiconductor chip.

7. The semiconductor package of claim 1, wherein the first semiconductor substrate comprises an active surface facing the first redistribution structure and an inactive surface opposite to the active surface, and
the first semiconductor chip further comprises:
a first interconnect structure between the active surface of the first semiconductor substrate and the first redistribution structure, the first interconnect structure comprising a first interconnect pattern electrically connected to the first through-electrode; and
a first backside interconnect structure on the inactive surface of the first semiconductor substrate, the first backside interconnect structure comprising a first backside interconnect pattern electrically connected to the first through-electrode.

8. The semiconductor package of claim 7, wherein the second semiconductor chip comprises:
a second semiconductor substrate comprising an active surface facing the first semiconductor chip and an inactive surface facing the second redistribution structure; and
a second interconnect structure between the active surface of the second semiconductor substrate and the first semiconductor chip, the second interconnect structure comprising a second interconnect pattern.

9. The semiconductor package of claim 7, wherein the second semiconductor chip comprises:
a second semiconductor substrate comprising an inactive surface facing the first semiconductor chip and an active surface facing the second redistribution structure;
a second through-electrode extending through the second semiconductor substrate;
a second interconnect structure on the active surface of the second semiconductor substrate, the second interconnect structure comprising a second interconnect pattern electrically connected to the second through-electrode; and
a second backside interconnect structure between the inactive surface of the second semiconductor substrate and the first semiconductor chip, the second backside interconnect structure comprising a second backside interconnect pattern electrically connected to the second through-electrode.

10. The semiconductor package of claim 9, further comprising a connection bump between the second semiconductor chip and the second redistribution structure,
wherein each of the inter-chip connection bump and the connection bump comprises solder.

11. The semiconductor package of claim 1, further comprising an upper semiconductor device on the second redistribution structure.

12. The semiconductor package of claim 11, wherein at least one of the first semiconductor chip and the second semiconductor chip comprises a logic chip, and
the upper semiconductor device comprises a memory chip.

13. The semiconductor package of claim 1, wherein each of the first vertical connection wire and the second vertical connection wire comprises copper, gold, or silver.

14. The semiconductor package of claim 1, wherein the first redistribution pattern comprises a first redistribution via that extends in a vertical direction in the first redistribution insulating layer,
the second redistribution pattern comprises a second redistribution via that extends in the vertical direction in the second redistribution insulating layer,
the first redistribution via has a tapered shape having a decreasing horizontal width in a direction toward an upper surface of the first redistribution structure, and
the second redistribution via has a tapered shape having a decreasing horizontal width in a direction away from a lower surface of the second redistribution structure.

15. A semiconductor package comprising:
a first redistribution structure comprising a first redistribution pattern and a first redistribution insulating layer;
a first semiconductor chip on the first redistribution structure, the first semiconductor chip comprising a first semiconductor substrate and a first through-electrode extending through the first semiconductor substrate;
a first conductive connection pillar extending between a first lower connection pad of the first semiconductor chip and a first redistribution pad of the first redistribution structure;
a second semiconductor chip on the first semiconductor chip and electrically connected to the first through-electrode, wherein an outer portion of the second semiconductor chip is laterally offset from a sidewall of the first semiconductor chip;
an inter-chip connection bump between the first semiconductor chip and the second semiconductor chip;
a second conductive connection pillar extending between a second lower connection pad of the second semiconductor chip and the inter-chip connection bump;
a molding layer in contact with the first redistribution structure, the sidewall of the first semiconductor chip, a sidewall of the second semiconductor chip, and the inter-chip connection bump;
a second redistribution structure on the second semiconductor chip and the molding layer, the second redistribution structure comprising a second redistribution pattern and a second redistribution insulating layer;
a first vertical connection conductor extending through the molding layer between the first redistribution structure and the second redistribution structure; and
a second vertical connection conductor extending through the molding layer between the first redistribution structure and the second semiconductor chip.

16. The semiconductor package of claim 15, wherein each of the first conductive connection pillar and the second conductive connection pillar comprises copper, and
the inter-chip connection bump comprises solder.

17. The semiconductor package of claim 15, wherein a portion of the molding layer is between the first semiconductor chip and the first redistribution structure and is in contact with a sidewall of the first conductive connection pillar, and
another portion of the molding layer is between the first semiconductor chip and the second semiconductor chip and is in contact with a sidewall of the second conductive connection pillar.

18. The semiconductor package of claim 15, wherein each of the first vertical connection conductor and the second vertical connection conductor comprises a vertical connection wire formed by a wire bonding process.

19. A semiconductor package comprising:
a first redistribution structure comprising a first redistribution pattern and a first redistribution insulating layer;
a first semiconductor chip on the first redistribution structure, the first semiconductor chip comprising a first semiconductor substrate and a first through-electrode extending through the first semiconductor substrate;
a first conductive connection pillar between the first semiconductor chip and the first redistribution structure and comprising copper;
a second semiconductor chip on the first semiconductor chip, the second semiconductor chip comprising a central portion vertically overlapping the first semiconductor chip and an outer portion horizontally offset from a sidewall of the first semiconductor chip;
an inter-chip connection bump between the first semiconductor chip and the second semiconductor chip and comprising solder;
a second conductive connection pillar between the inter-chip connection bump and the second semiconductor chip and comprising copper;
a molding layer in contact with the first redistribution structure, the first semiconductor chip, the second semiconductor chip, the first conductive connection pillar, the second conductive connection pillar, and the inter-chip connection bump;
a second redistribution structure on the second semiconductor chip and the molding layer, the second redistribution structure comprising a second redistribution pattern and a second redistribution insulating layer;
an upper semiconductor chip on the second redistribution structure;
a first vertical connection wire extending through the molding layer between a first bonding pad of the first redistribution structure and a second bonding pad of the second redistribution structure; and
a second vertical connection wire extending through the molding layer between a third bonding pad of the first redistribution structure and a fourth bonding pad of the second semiconductor chip,
wherein a contact area between the first vertical connection wire and the second bonding pad is greater than a contact area between the first vertical connection wire and the first bonding pad, and
a contact area between the second vertical connection wire and the fourth bonding pad is greater than a contact area between the second vertical connection wire and the third bonding pad.

20. The semiconductor package of claim 19, wherein the first semiconductor substrate comprises an active surface facing the first redistribution structure and an inactive surface opposite to the active surface,
the first semiconductor chip further comprises:
a first interconnect structure between the active surface of the first semiconductor substrate and the first redistribution structure, the first interconnect structure comprising a first interconnect pattern electrically connected to the first through-electrode; and
a first backside interconnect structure on the inactive surface of the first semiconductor substrate, the first backside interconnect structure comprising a first backside interconnect pattern electrically connected to the first through-electrode, and
the second semiconductor chip comprises:
a second semiconductor substrate comprising an active surface facing the first semiconductor chip and an inactive surface facing the second redistribution structure; and
a second interconnect structure between the active surface of the second semiconductor substrate and the first semiconductor chip and comprising a second interconnect pattern.

21-27. (canceled)
